(19) United States
(12) Patent Application Publication
(10) Pub. No.: US 2026/0360451 A1
(43) Pub. Date: Nov. 12, 2026

(54) FLAG DATA STORAGE WITH MEMORY CELLS ARRAY

(71) Applicant: Micron Technology, Inc., Bosie, ID (US)

(72) Inventors: Tomoharu Tanaka, Yokohama (JP); Tomoko Ogura Iwasaki, San Jose, CA (US)

(73) Assignee: Micron Technology, Inc., Boise, ID (US)

(21) Appl. No.: 19/653,669

(22) Filed: Apr. 21, 2026

Related U.S. Application Data
(60) Provisional application No. 63/801,705, filed on May 7, 2025.

(51) Int. Cl. G11C 16/34; G11C 16/10; G11C 16/26

(52) U.S. Cl. CPC G11C 16/3459; G11C 16/102; G11C 16/26

(57) ABSTRACT

A memory device is provided. The device comprises a memory plane having a first sub-plane and a second sub-plane, a global bit line and control logic. The first sub-plane includes a first group of memory cells configured to operate as a first-type storage and a first group of memory cells configured to operate as a second-type storage. The second sub-plane includes a second group of memory cells configured to operate as the first-type storage and a second group of memory cells configured to operate as the second-type storage, the control logic is configured to perform one or more data sensing operations and store flag data associated with the data sensing operations in the second or first group of memory cells configured to operate as the second-type storage.

### CROSS-REFERENCE TO RELATED APPLICATIONS

This application claims priority to U.S. Provisional Patent Application Ser. No. 63/801,705, filed May 7, 2025, entitled “FLAG DATA STORAGE WITH MEMORY CELLS ARRAY”. The contents of the application referenced in this section are hereby incorporated by reference in their entirety for all purposes.

### TECHNICAL FIELD

This disclosure relates to one or more systems for memory, including techniques for a memory device configuration in which some memory cells are configured as temporary cache for storing data associated with sensing selected memory cells.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not- or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory cells in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more methods described herein, in accordance with examples as disclosed herein.

FIGS. 4A and 4B illustrate an example three-dimensional structure of a memory device in accordance with examples as disclosed herein.

FIG. 5 illustrates an example of a memory plane including a top sub-plane and a bottom sub-plane within a memory device in accordance with examples as disclosed herein.

FIG. 6 is an illustrative schematic of the first and second sub-planes in a memory device in accordance with examples as disclosed herein.

FIG. 7 illustrates a schematic of the memory cells configured to operate as the second-type storage within a memory device, in accordance with examples as disclosed herein.

FIG. 8 illustrates a flowchart showing a method for storing flag data associated with sensing from selected memory cells in accordance with examples as disclosed herein.

FIG. 9 illustrates a flowchart showing a program method performed by the memory device in accordance with examples as disclosed herein.

### DETAILED DESCRIPTION

Aspects of the present disclosure are directed to a memory plane arrangement of a memory array in a memory device. Such a memory plane arrangement uses dynamic latches to enable non-volatile memory cells (e.g., NAND flash cells) to be used as temporary volatile storage to store flag data associated with sensing selected memory cells. A memory device can include one or more memory planes. For some types of non-volatile memory devices (e.g., NAND memory device), each memory plane includes of a set of physical memory blocks (or simply “blocks”). Each block includes a set of sub-blocks. Each sub-block includes a string of memory cells. A memory cell is an electronic circuit that stores information. Depending on the cell type, a cell can store charges representing one or more bits of binary information, and has various logic states that correlate to the number of bits being stored. The logic states can be represented by binary values, such as “0” and “1”, or combinations of such values.

A memory device includes memory cells arranged in a two-dimensional or a three-dimensional grid. Memory cells are formed onto a semiconductor (e.g., silicon) wafer in an array of columns or strings and rows. Each column of memory cells corresponds to a sub-block of memory cells that are connected to a same bit line. Each row of memory cells is connected to a same word line. The intersection of a bit line and word line constitutes the address of the memory cell. A block hereinafter refers to a unit of the memory device used to store data and can include many sub-blocks (e.g., many strings of memory cells each connected to a bit line). The sub-blocks in a memory block are typically connected to a global bit line for performing read and program operations. The global bit line is connected to a page buffer. One or more blocks can be grouped together to form separate partitions (e.g., planes) of the memory device in order to allow concurrent operations to take place on each plane. A plane can be divided into two sub-planes (e.g., top and bottom sub-planes), such that the operations performed on each sub-plane can be processed independently. An example memory device with blocks and sub-blocks are described in greater detail below.

The page buffer typically includes a sense amplifier configured to sense data through the global bit line and latches configured to store the sensed data. The page buffer, during a data sensing operation (e.g., a read operation or a program verify operation), stores the data sensed from the selected memory cells in the latches.

The data latches in a page buffer usually takes a large chip area (e.g., a page buffer may account for 50% of the chip area in some instances). In order to reduce the size of page buffer, some latches can be moved from page buffer and data can instead be stored to an array of memory cells. However, the modification of data in the memory array is challenging due to lack of devices required for the modification in the array. As a result, the page buffer needs to intervene in the modification, leading to increased overhead time in data sensing operations.

Thus, to reduce the size of the page buffer and decrease the overhead time, it is desirable to configure certain memory cells within the memory array to function as a cache for temporarily storing data sensed from selected memory cells. That is, during data sensing operations, the sensed data and/or data associated with the sensing operations (e.g., flag data) can be stored in other memory cells within the array instead of in the page buffer latches. Additionally, an improved method for storing and modifying sensed data efficiently is needed.

Aspects of the present disclosure address the above challenges and other deficiencies by dividing each of the two sub-planes in a memory plane into two groups of memory cells and using a dynamic latch structure to enable temporary data storage in one sub-plane for data associated with sensing operations performed in the other sub-plane. For example, a memory plane is divided into a first sub-plane and a second sub-plane. The first sub-plane (e.g., a top sub-plane) includes a first group of memory cells configured to operate as a first-type storage and a first group of memory cells configured to operate as a second-type storage. Similarly, the second sub-plane (e.g., a bottom sub-plane) includes a second group of memory cells configured to operate as the first-type storage and a second group of memory cells configured to operate as the second-type storage. In one example, the memory cells designated as first-type storage function as conventional memory cells (e.g., NAND) for data storage, whereas the memory cells designated as second-type storage serve as a temporary cache (e.g., DRAM) for storing flag data associated with sensing from the first-type storage memory cells. Thus, the memory cells in the first sub-plane and in the second sub-plane, while physically the same, are configured to use as different types of storage (e.g., non-volatile storage like NAND and volatile storage like DRAM).

One type of data sensing operation is a program verify operation. During a program verify operation, when a selected memory cell configured to operate as the first-type storage on the first sub-plane is verified, certain memory cells configured to operate as the second-type storage on the second sub-plane function as a temporary cache to store flag data generated during the sensing operations of the selected memory cell. In other words, when a selected memory cell in the first sub-plane undergoes verification, certain memory cells in the second sub-plane can serve as a temporary cache, and vice versa. As described in greater detail below, dynamic latches are included in each of the sub-planes, enabling one sub-plane to function as a temporary cache while the other sub-plane is undergoing a data sensing operation. As a result, the efficiency of data sensing operation is improved and the need for latches in the page buffer is reduced.

Moreover, since the first sub-plane (e.g., top sub-plane) and the second sub-plane (e.g., bottom sub-plane) are coupled to different sets of word lines, data stored in the two sub-planes can be modified independently. For example, the memory cells in the first sub-plane are coupled to a first set of word lines, while the memory cells in the second sub-plane are coupled to a second set of word lines. The second set of word lines are different from the first set of word lines. During a program verify operation, a specific voltage can be applied to the first set of word lines to sense data stored in the selected memory cells in the first sub-plane, while a different voltage is applied to the second set of word lines to modify the data stored in memory cells functioning as a temporary cache in the second sub-plane. This configuration enables independent operation of the selected memory cells to be verified and the temporary cache memory cells, preventing interference between them.

In some examples, two sets of memory cells are used to store flag data for each selected memory cell. The data stored in the first set of memory cells indicates the states of whether the corresponding selected memory cell has reached its target program level, while the data stored in the second set indicates the states of whether the selected memory cell is approaching its target program level. During a subsequent program operation, the selected memory cells are applied with a program voltage based on the states of the two sets of memory cells. The combined information from both sets provides a more precise indication of the required program voltage, thereby enhancing programming accuracy and efficiency.

The flag data may be obtained using a current meter. In some examples, a current meter can be coupled to the source line of the memory plane to measure the total current flowing through memory cells configured to operate as the second-type storage. For example, the first set of memory cells includes a first cumulative flag memory cell indicating whether the corresponding selected memory cell has reached its target program level. The current meter can measure the total current flowing through the first cumulative flag memory cells for all selected memory cells. When all first cumulative flag memory cells are in a low state, the measured total current is zero or substantially zero (e.g., with negligible leaky currents), indicating that all selected memory cells have been programmed to their target program level. Thus, the programming status of all selected memory cells can be checked based on current measurements.

In some examples, the successful programming of the selected memory cells may be determined based on the detected level state of the global bit line. The level state of the global bit line is influenced by sense memory nodes in a first and second dynamic latch devices coupled to the first and second sub-plane respectively. The dynamic latch devices are disposed between the global bit line and the sub-blocks of memory cells (e.g., strings of memory cells). The dynamic latch devices include transistors (e.g., thin-film transistors) for controlling the transfer of sensed data from a selected memory cell to the global bit line. As described in greater detail below, when both thin-film transistors (TFTs) in the first and second dynamic latch devices are inactive, the global bit line is at a high level, indicating that the selected memory cell has not yet been programmed. When the TFT in the first dynamic latch is active while the TFT in the second dynamic latch is inactive, the bit line is at a low level, indicating that the selected memory cell has just been programmed. When both TFTs are active, the bit line remains at a low level, indicating that the selected memory cell was previously programmed. If the TFT in the second dynamic latch is active while the TFT in the first dynamic latch is inactive, the bit line remains at a low level, indicating that a program voltage for a higher state has been mandatorily ignored. Therefore, the dynamic latch devices enabling the implementation of a logic gate (e.g., NOR gate) for providing the programming status, without requiring of using an actual digital logic gate.

Advantages of this approach include, but are not limited to, reducing the size of the page buffer and decreasing the overhead time. By storing flag data within the memory cell array instead of the page buffer, fewer latch devices are required in the page buffer, thereby significantly reducing its size. Furthermore, the flag data stored in memory cells functioning as a temporary cache is represented in a simple “low” or “high” form, facilitating easy modification and updates. As a result, the need for page buffer intervention in data modification is eliminated, thereby reducing overhead time.

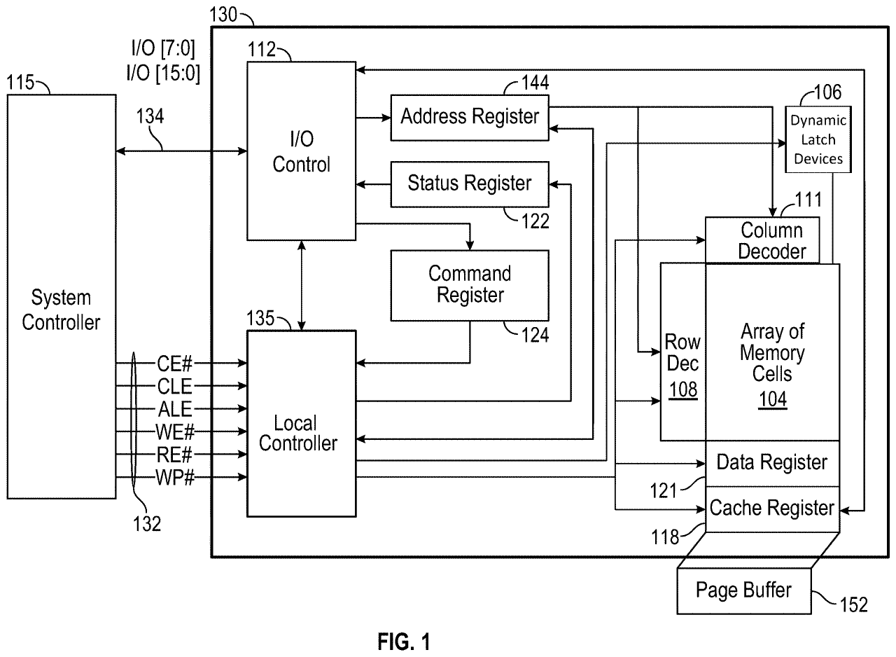

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115. For example, the local controller 135, on its own or in response to a command provided by external system controller 115, is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses. A memory controller (e.g., the local controller 135 or the system controller 115) is also referred to as control logic in this disclosure.

In some examples, local controller 135 communicates with the external system controller 115, which may be a host controller (e.g., an UFS or eMMC controller, or a CPU communicating with local controller 135) located in a host system or a memory system controller located in a memory system. In some examples, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some examples, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some examples, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

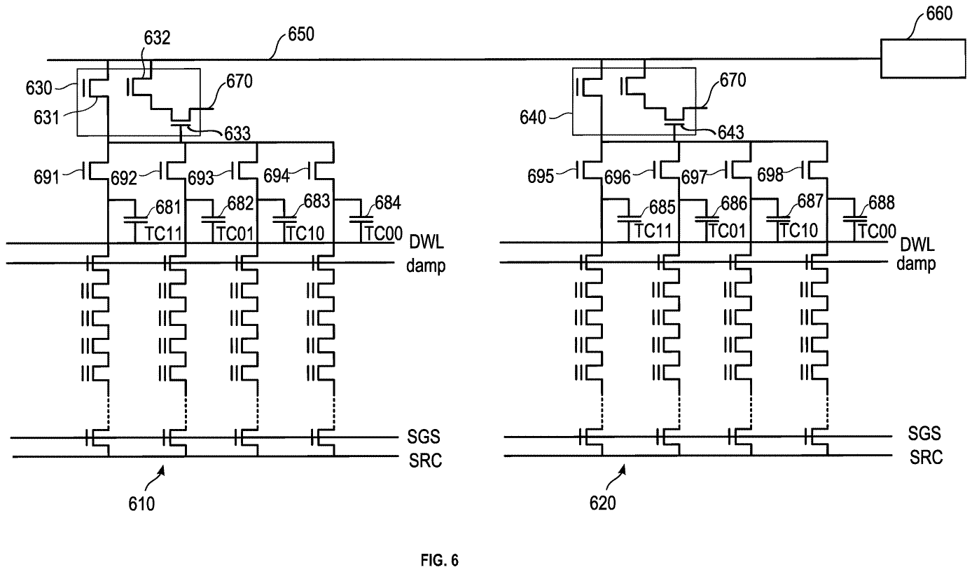

FIG. 1 also illustrates that dynamic latch devices 106 can be disposed above the array of memory cells 104, where the page buffer 152 is normally disposed below the array 104. Dynamic latch devices 106 are connected to the sub-blocks of memory blocks in the array of memory cells 104. Dynamic latch devices 106 are also connected to a global bit line (shown in FIG. 6).

As shown in FIG. 1, memory device 130 receives various control signals via local controller 135 from system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 144. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

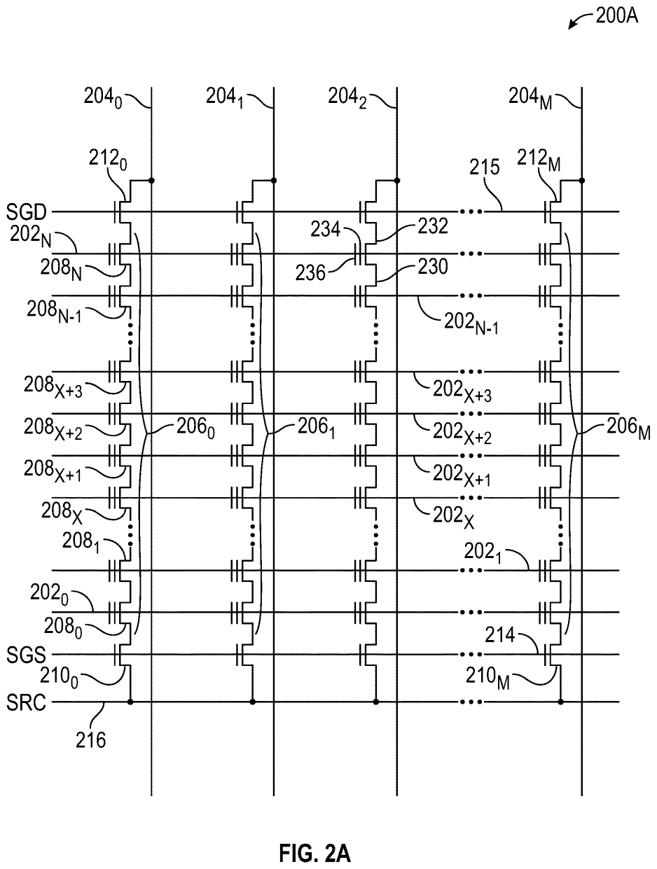

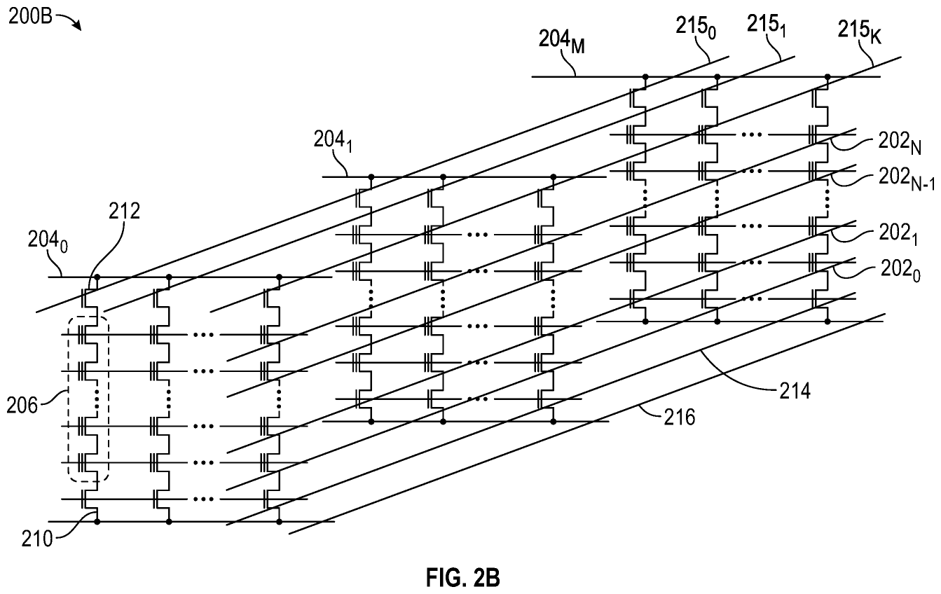

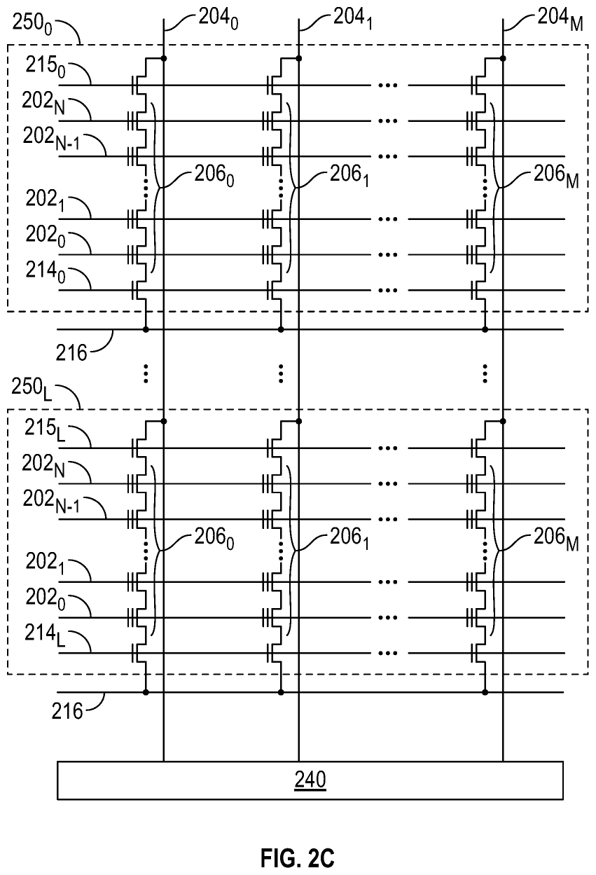

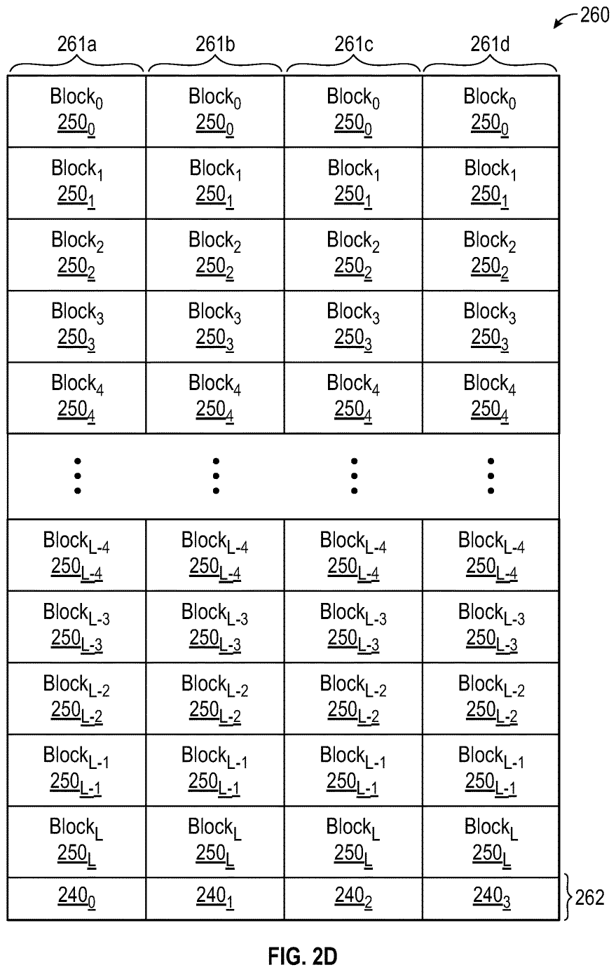

FIG. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some examples, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some examples, each sub-block or string of memory cells has a separate select line 214 from other sub-blocks or strings. In some examples, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204. In one example, buffer portion 240 can be a part of page buffer 152. As described below, multiple buffer portions 240 may collectively form a page buffer 152.

FIG. 2D is a block schematic of a portion of an example array of memory cells 260. Array of memory cells 260 can be used as array 104 in a memory device 130. The array of memory cells 260 is depicted as having four memory planes 261 (e.g., memory planes 261a-261d). Each of the memory planes 261 may refer to a group of memory blocks of memory cells 250. Each memory plane 261 can be in communication with a respective buffer portion 240, which can collectively form a page buffer 262. Page buffer 262 may be used to implement page buffer 152 shown in FIG. 1. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

In some cases, concurrent operations may be performed on different planes. For example, concurrent operations may be performed on memory cells within different blocks 250 so long as the different blocks 250 are in different planes 261. In some cases, an individual memory block 250 may be referred to as a physical block, and a virtual block may refer to a group of blocks 250 within which concurrent operations may occur. For example, concurrent operations may be performed on four blocks of 250₀ that are within planes 261a, 261b, 261c, and 261d, respectively, and the four blocks of 250₀ may be collectively referred to as a virtual block. In some cases, a virtual block may include blocks from different memory devices. In some cases, the physical blocks within a virtual block may have the same block address within their respective planes. In some cases, performing concurrent operations in different planes 261 may be subject to one or more restrictions, such as concurrent operations being performed on memory cells within different pages that have the same page address within their respective planes 261 (e.g., related to command decoding, page address decoding circuitry, or other circuitry being shared across planes 261).

In some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page may, in some cases, not be updated until the entire block that includes the page has been erased.

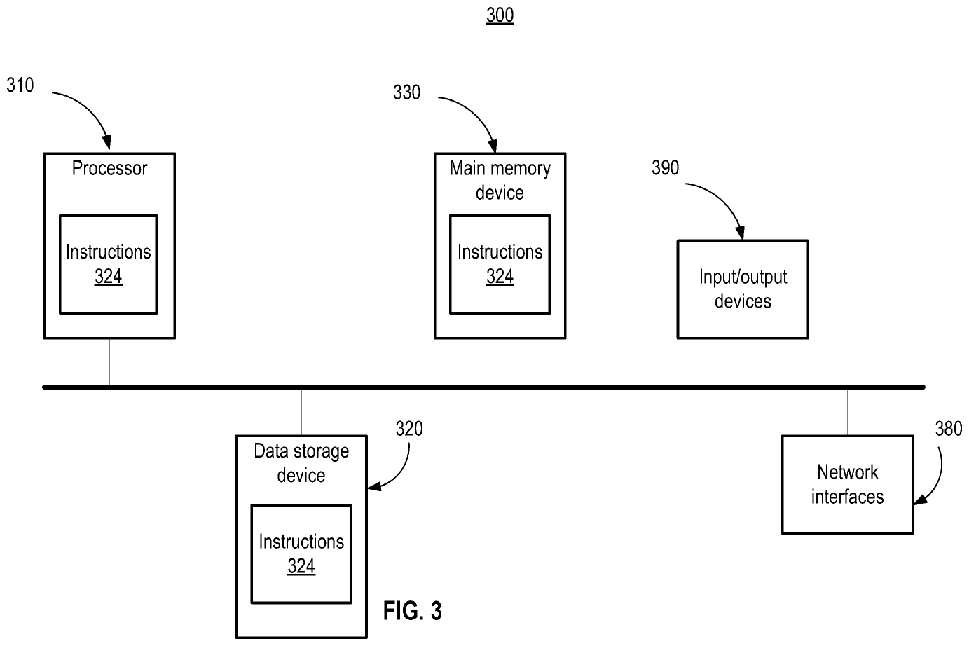

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-9, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 1-9 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-9. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

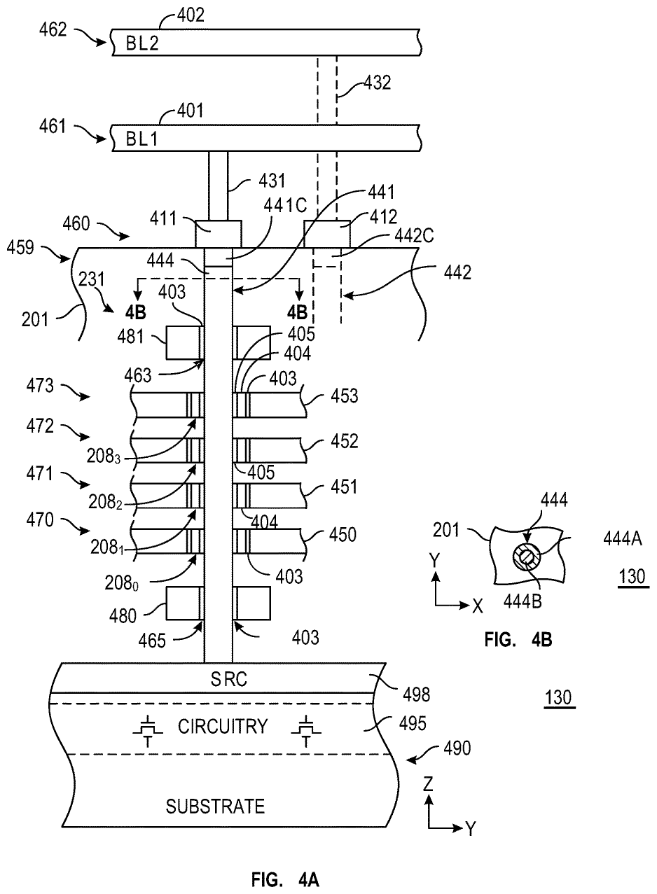

FIG. 4A-FIG. 4B shows a side view (e.g., a cross section with respect to the X-Z directions) of a portion of the three-dimensional structure of memory device 130 including a structure of memory cell string 231 (e.g., a NAND string) having a pillar 441, according to some embodiments described herein. FIG. 4A shows the structure of one memory cell string (e.g., memory cell string 231) of memory device 130. However, other memory cell strings (e.g., NAND strings 206₀-206_{M} in FIG. 2A and NAND strings 206 in FIG. 2B) can have a similar or the same structure as memory cell string 231 shown in FIG. 4A.

Starting from the top of FIG. 4A, memory device 130 have data lines 401 and 402 (e.g., corresponding to bit lines 204 in FIGS. 2A, 2B, and 2C) coupled to conductive structures 431 and 432, respectively, and coupled to conductive contacts 411 and 412, respectively. Data lines 401 and 402 are therefore electrically connected to pillars 441 and 442, respectively, via the conductive contacts 411 and 412, respectively. It is understood that memory device 130 can include many other similar data lines, conductive structures, and conductive contacts, which are not shown for simplicity.

FIGS. 4A-4B shows directions X, Y, and Z that can be relative to the physical directions (e.g., dimensions) of the structure of memory device 130. For example, the Z-direction can be a direction perpendicular to (e.g., vertical direction relative to) a substrate (e.g., a semiconductor substrate) of memory device 130. The Z-direction is perpendicular to the X-direction and Y-direction (e.g., the Z-direction is perpendicular to an X-Y plane of memory device 130).

As shown in FIG. 4A, data lines 401 and 402 can carry signals (e.g., bit line signals) BL1 and BL2, respectively. In the physical structure of memory device 130, data lines 401 and 402 can be structured as conductive lines and have respective lengths extending in the Y-direction. The data lines (e.g., data lines 401 and 402) of memory device 130 can be formed on different levels (e.g., layers) in the physical structure of memory device 130. For example, data lines 401 can be formed on one level (e.g., a lower level 461) of memory device 130, and data lines 402 can be formed on another level (e.g., an upper level 462) of memory device 130. Although not shown in FIG. 4A, multiple data lines can be located side-by-side in any particular level. For example, level 461 may have multiple data lines and level 462 may also have multiple data lines. Data lines in the same level can be separated from each other by a distance (e.g., a gap) in the X-direction. The gaps between data lines in the same level may be the same or different. As shown in FIG. 4A, each of data lines 401 and 402 can have a thickness in the Z-direction and a width in the X-direction. Each of the thickness (in the Z-direction) and the width (in the X-direction) is less than the length (in the Y-direction). The thickness can be less than, equal to, or greater than the width.

In FIG. 4A, each of conductive structures 431 and 432 can have a length extending in the Z-direction. In some examples, the length of conductive structure 431 can be less than the length of conductive structure 432, because level 461 is a lower level that is located closer to memory array 201. Each of conductive structures 431-432 can include (e.g., can be formed from) a conductive material that extends in the Z-direction. Examples of the conductive material include metal, alloy, conductively doped polysilicon, or other conductive materials. Although not shown in FIG. 4A, memory device 130 can include a dielectric material (e.g., silicon dioxide) formed between levels 462 and 461. The dielectric material can be formed before conductive structures 431 and 432. Then, openings (e.g., holes (e.g., vertical vias)) can be formed in the dielectric material. The material of each of conductive structures 431-432 can be formed (e.g., deposited) inside a respective opening of the openings.

As shown in FIG. 4A, each of conductive structures 431 and 432 can be coupled to (e.g., in electrical contact with) a respective conductive contact among conductive contacts 411 and 412 and coupled to (e.g., in electrical contact with) a respective data line among data lines 401 and 402. For example, conductive structure 431 can include an end (e.g., bottom end) coupled to (e.g., directly contacting) conductive contact 411, and another end (e.g., top end) coupled to (e.g., directly contacting) data line 401. In another example, conductive structure 432 can include an end (e.g., bottom end) coupled to (e.g., directly contacting) conductive contact 412, and another end (e.g., top end) coupled to (e.g., directly contacting) data line 402.

As shown in FIG. 4A, memory cell string 231 can include pillars (e.g., vertical pillars) 441 and 442. Pillars 441 and 442 can include pillar contacts 441C and 442C, respectively, located on the same level (e.g., level 459) of memory device 130. Pillars 441 and 442 can be located under (e.g., directly under) respective conductive contacts 411 and 412, which are under (e.g., directly under) respective conductive structures 431 and 432. Conductive structures 431 and 432 can be coupled to (e.g., in electrical contact with) pillars 441 and 442, respectively, through conductive contacts 411 and 412, respectively. Thus, as shown in FIG. 4A, data lines 401 and 402 can be coupled to (e.g., electrically coupled to) pillars 441 and 442, respectively, through respective conductive structures 431 and 432 and respective conductive contacts 411 and 412.

As described above, data lines 401 and 402 are located in levels 461 and 462, respectively. Levels 461 and 462 are in portion of memory device 130 that is located above memory array 201 in the Z-direction. Memory array 201 is located above a substrate 490 of memory device 130 in the Z-direction. As described above, a memory array such as memory array 201 comprises multiple memory cell strings (one of which is shown as memory cell string 231).

As shown in FIG. 4A, pillar (e.g., a vertical pillar) 441 can be a part of memory cell string 231 and can have a length extending in the Z-direction (e.g., extend vertically with respect to substrate 490). Pillar 441 can extend through memory cells 208₀, 208₁, 208₂, and 208₃ of memory cell string 231. Pillar 441 can include (e.g., can be formed from) a conductive material (e.g., conductively doped polysilicon). Each of memory cells 208₀, 208₁, 208₂, and 208₃ can include a structure of transistor (e.g., a memory cell transistor). Part of pillar 441 can form the channel region (e.g., to conduct current) of the transistor of each memory cells 208₀, 208₁, 208₂, and 208₃. It is understood that while FIG. 4A only shows four memory cells 208₀-208₃, memory cell string 231 can include any number of memory cells that share a same pillar (e.g., pillar 441).

As described above, pillar contact 441C can be formed from conductively doped polysilicon, metal, or other conductive materials. Pillar 441 can include a portion 444. Pillar contact 441C and portion 444 of pillar 441 can include the same conductive material or different conductive materials. Conductive structure 431, conductive contact 411, and pillar 441 can be part of a circuit path (e.g., a conductive channel of memory cell string 231) between data line 401 and a conductive region 498 (associated with an SRC line). Conductive region 498 can be a part of a common source line (e.g., common source line or source plate 216 in FIG. 2A). Conductive structure 431 and pillar 441 can have the same material or different materials. In FIG. 4A, during a memory operation (e.g., read or write operation) of memory device 130, a circuit path (e.g., a current path) can be formed between data line 401 and conductive region 498 through conductive structure 431, conductive contact 411, and pillar 441 (which includes pillar contact 441C and portion 444 of pillar 441).

Substrate 490 of memory device 130 can include a semiconductor substrate (e.g., silicon-based substrate). For example, substrate 490 can include a p-type silicon substrate or an n-type silicon substrate. As shown in FIG. 4A, memory cells 208₀, 208₁, 208₂, and 208₃ of memory cell string 231 can be located along (e.g., adjacent) respective portions of pillar 441 in different levels (in the Z-direction) of memory device 130. For example, memory cells 208₀, 208₁, 208₂, and 208₃ can be located one over another (e.g., formed vertically) in levels 470, 471, 472, and 473, respectively, of memory device 130. Memory cells of other memory cell strings of memory device 130 can also be located on respective levels 470, 471, 472, and 473.

By stacking the memory cells in different levels, the memory device forms a 3D structure that has a higher capacity than a 2D device. In a typical 3D memory device (e.g., device 130 shown in FIG. 4A), for example, multiple levels (e.g., levels 470, 471, 472, and 473) are stacked together with one or more memory pillars (e.g., pillars 441 and 442) disposed vertically in the middle. The memory pillars may act as the channel region of the memory device. The multiple levels (e.g., layers or tiers) of the memory device may form groups or decks. A deck of a 3D memory device may be processed together (e.g., patterned and/or etched together) when forming the memory pillar associated thereof. A level of the memory device may have one or more access lines (e.g., word lines) or access line groups (e.g., word line groups). Each deck may have one or more access line segments (e.g., word line segments). An access line segment may have fewer or more access lines than those in a deck. For example, a deck may have two word line segments distributed in one or more levels. In some cases, certain memory operations (e.g., an erase operation) can be performed to a word line group (e.g., a deck), and not to the entire memory block. By not performing an operation to the entire memory block, the particular operation may be performed faster.

FIG. 4A further illustrates that access lines 450, 451, 452, and 453 of memory device 130 can be located along (e.g., adjacent) respective portions (in the Z-direction) of pillar 441 in the same levels (e.g., levels 470, 471, 472, and 473, respectively) that memory cells 208₀, 208₁, 208₂, and 208₃ are located. Access lines can include, for examples, word lines or control gates. Access lines 450, 451, 452, and 453 can include (e.g., can be formed from) a conductive material (or materials). Example materials for access lines 450, 451, 452, and 453 include metal, alloy, doped polysilicon, other conductive materials.

In FIG. 4A, a select line (e.g., drain select gate or SGD) 481 can have a length extending in the X-direction (e.g., perpendicular to the lengths (in the Y-direction) of data lines 401 and 402). The materials of select line 481 can include a conductive material (e.g., conductively doped polysilicon, metal, other conductive material). FIG. 4A shows an example where another select line (e.g., source select gate or SGS) 480 can have a structure (e.g., shape, material, or both) similar to (or the same as) that of select line 481. In some examples, select line 480 can have a structure (e.g., shape, material, or both) similar to (or the same as) that of each of access lines 450, 451, 452, and 453.

As shown in FIG. 4A, a transistor (e.g., source select transistor) 465 and a transistor (e.g., drain select transistor) 463 can be located along (e.g., adjacent) respective portions of pillar 441 in the Z-direction. Memory cells 208₀, 208₁, 208₂, and 208₃ of memory cell string 231 can be located along the portion of pillar 441 that is between transistors 465 and 463.

Memory cell string 231 can include materials 403, 404, and 405 formed between portion 444 of pillar 441 and a respective access line among access lines 450, 451, 452, and 453. Material 403 can also be formed between pillar 441 and each of select lines 480 and 481. Materials 403, 404, and 405 located at a particular memory cell (among memory cells 208₀, 208₁, 208₂, and 208₃) can be a part (e.g., a memory element) of that particular memory cell. As shown in FIG. 4A, the combination of materials 403, 404, and 405 of a memory cell (among memory cells 208₀, 208₁, 208₂, and 208₃) can be separated from (in the Z-direction) the combination of materials 403, 404, and 405 of another memory cell (among memory cells 208₀, 208₁, 208₂, and 208₃).

Material 403 can include a charge blocking material (or charge blocking materials), for example, a dielectric material (e.g., silicon nitride) that is capable of blocking a tunneling of a charge. Material 404 can include a charge storage material (or charge storage materials) that can provide a charge storage function to represent a value of information stored in memory cells 208₀, 208₁, 208₂, and 208₃. For example, material 404 can include polysilicon (e.g., conductively doped polysilicon), which can be either a p-type polysilicon or an n-type polysilicon. The polysilicon can be configured to operate as a floating gate (e.g., to store charge) in a memory cell (e.g., a memory cell 208₀, 208₁, 208₂, and 208₃). In another example, material 404 can include a dielectric material (e.g., silicon-nitride based material or other dielectric materials) that can trap charge in a memory cell (e.g., a memory cell 208₀, 208₁, 208₂, and 208₃). Material 405 can include a tunnel dielectric material (or tunnel dielectric materials), for example, silicon dioxide, that is capable of allowing tunneling of a charge (e.g., electrons).

As shown in FIG. 4A, memory device 130 can include circuitry 495 located (e.g., formed) under memory array 201 (e.g., located directly under memory cell string 231). Circuitry 495 can include circuit elements (e.g., transistors T) coupled to other circuit elements (e.g., coupled to data lines 401-402) of memory device 130. The circuit elements (e.g., transistors T) of circuitry 495 can be configured to perform part of a function of a memory device (e.g., memory device 130). For example, circuitry 495 can include decoder circuits, driver circuits, buffers (e.g., page buffers), sense amplifiers, charge pumps, and other circuitry of memory device 130. In an alternative structure of memory device 130, circuitry 495 can be located (e.g., formed) above memory array 201 (instead of under memory array 201). For example, in the alternative structure of memory device 130, circuitry 495 can be located above memory array 201 and under data lines 401 and 402, or located between data lines 401 and 402 of memory array 201 in the Z-direction. In another example, in the alternative structure of memory device 130, circuitry 495 can be located above memory array 201 and above data lines 401 and 402 in the Z-direction.

A different view of pillar 441 along a cross-sectional line 4B-4B is shown in FIG. 4B. FIG. 4B shows a top view (e.g., a cross section with respect to the X-Y plan) of portion 444 of pillar 441 along line 4B-4B of FIG. 4A. As shown in FIG. 4B, portion 444 of pillar 441 can include material 444A and material 444B surrounded by material 444A. Material 444A can be (or can include) a part of a conductive structure (e.g., a conductive channel) of pillar 441. Material 444B can include a dielectric material. In an alternative structure of pillar 441, material 444B can be omitted from pillar 441, such that the entire portion 444 of pillar 441 can include material 444A (without material 444B).

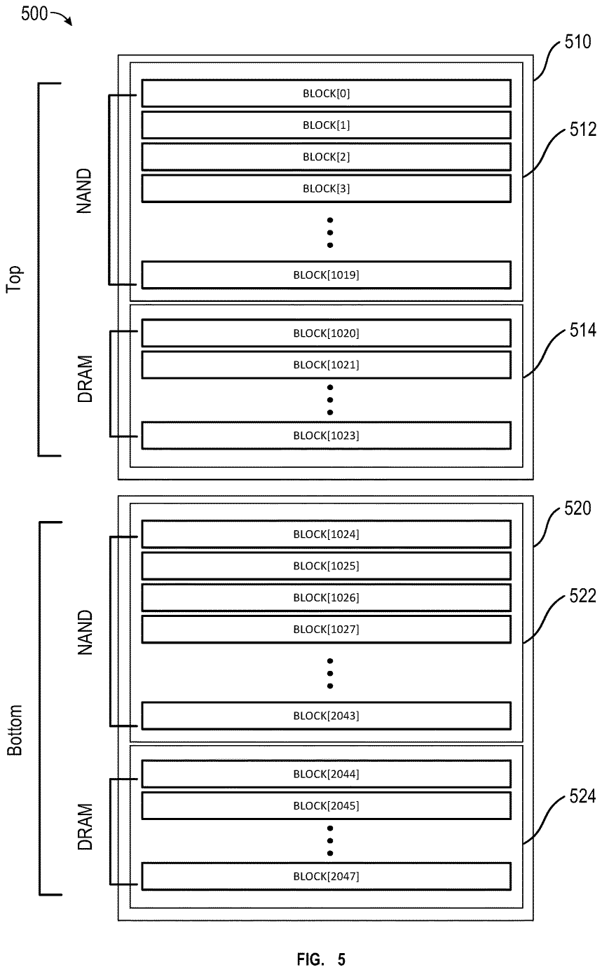

FIG. 5 illustrates an example of a memory plane 500 within a memory device in accordance with examples as disclosed herein. Memory plane 500 can be any of the memory plane 261 as described above. In one example, memory plane 500 can include a first sub-plane 510 and a second sub-plane 520. As shown in FIG. 5, the first sub-plane 510 is positioned at the upper portion of the memory plane 500 (hereafter referred to as the “top sub-plane”), while the second sub-plane 520 is positioned at the lower portion of the memory plane 500 (hereafter referred to as the “bottom sub-plane”). It is understood that the top and bottom portions are for differentiating the sub-planes, and thus can be interchanged. For example, in FIG. 5, the top sub-plane can be termed the bottom sub-plane, and vice versa. Both sub-planes include multiple memory blocks. Specifically, for example, the top sub-plane 510 contains 1024 memory blocks (e.g., block [0] through block [1023]), while the bottom sub-plane 520 contains an additional 1024 memory blocks (e.g., block [1024] through block [2047]). Although the example of FIG. 5 illustrates an equal number of memory blocks in each sub-plane, alternative configurations may allocate different numbers of memory blocks to each sub-plane. For instance, the top sub-plane may include more memory blocks than the bottom sub-plane, or vice versa.

In some examples, the first sub-plane 510 (e.g., the top sub-plane) includes two groups of memory cells: a first group of memory cells configured to operate as a first-type storage 512 and a first group of memory cells configured to operate as a second-type storage 514. Similarly, the second sub-plane 520 (e.g., the bottom sub-plane) includes two groups of memory cells: a second group of memory cells configured to operate as the first-type storage 522 and a second group of memory cells configured to operate as the second-type storage 524. In the example of FIG. 5, the first-type storage may be non-volatile storage (e.g., NAND), while the second-type storage may be volatile storage (e.g., DRAM). Specifically, memory blocks [0] through [1019] in the top sub-plane 510 are configured to operate as the first-type storage, while blocks [1020] through [1023] are configured to operate as the second-type storage. Likewise, memory blocks [1024] through [2043] in the bottom sub-plane 520 are configured to operate as the first-type storage, while blocks [2044] through [2047] are configured to operate as the second-type storage. The configuration shown in FIG. 5 is merely illustrative; other variations are possible. For example, the allocation of first-type and second-type storage within each sub-plane may be inverted, or the number of memory blocks allocated to each type may vary. The controller may be pre-configured to allocate memory blocks in each sub-plane to function as the first or second type of storages.

As described above, a memory device includes a global bit line (not shown in FIG. 5). During a program operation, a selected memory cell can be programmed by applying a specific voltage to the global bit line and applying a particular word line voltage to the word line connected to the selected memory cell. During a data sensing operation, the global bit line voltage can be modulated by a selected memory cell to retrieve stored data. The global bit line is connected to both the top and bottom sub-planes (e.g., planes 510 and 520), thereby linking all local bit lines within each sub-plane. This enables communication between the global bit line and either sub-plane independently. When the global bit line is configured to communicate with the top sub-plane 510, it can facilitate programming data to, and/or sensing data from, selected memory cells in the top sub-plane 510. Similarly, when configured to communicate with the bottom sub-plane 520, it can facilitate programming data to, and/or sensing data from, selected memory cells in the bottom sub-plane 520.

A memory device further includes control logic. The control logic may be a system controller 115 and/or local controller 135 of FIG. 1. The control logic is coupled to the memory plane 500. The control logic can be configured to perform one or more data sensing operations (e.g., a read operation, a program verify operation) in which selected memory cells in the first or second group of the memory cells configured to operate as the first-type storage 512 and 522 are sensed. The control logic can be configured to store flag data associated with the data sensing operations in the second or first group of memory cells configured to operate as the second-type storage 524 or 514 in one of the second or first sub-planes not containing the selected memory cells. The second type storage is configured as a cache (e.g., DRAM) to temporarily store the flag data indicating the status of the selected memory cells during the one or more data sensing operations.

For example, with reference to FIG. 5, during a program operation, if a selected memory cell within block [1] of the top sub-plane 510 is programmed, a subsequent program verify operation checks whether the memory cell has reached its target program level. During this verify operation, the data stored in the selected memory cell is read by the page buffer (e.g., by a sense amplifier) and temporarily stored in memory cells within block [2044] of the bottom sub-plane 520, which functions as a cache (e.g., a DRAM cache). Similarly, if a selected memory cell in block [1025] of the bottom sub-plane 520 requires verification, the data can be temporarily stored in memory block [1020] of the top sub-plane 510. Thus, memory cells configured to operate as the second-type storage within the bottom sub-plane 520 serve as a temporary cache when verifying selected memory cells in the top sub-plane 510, and vice versa.

As described above, during data sensing operations like the program verification, flag data are generated. The flag data described above indicates the status of selected memory cells during the programming operation. TABLE 1 illustrates how memory cells function as the second-type storage (e.g., cache) that stores the flag data of selected memory cells. At least one set of memory cells configured to operate as the second-type storage is used to temporarily store flag data for each corresponding selected memory cell. In FIG. 5, for instance, the memory cells configured to operate as the second-type storage 524 or 514 can be used to store the flag data generated during the programming operation. In some examples, a single set of memory cells stores flag data for one selected memory cell, whereas in other examples, two or more sets of memory cells can be used.

TABLE 1
two sets of memory cells configured to operate as
the second-type storage in their
initial states at the beginning of a program operation.

| | Cell | level | state |
|---|---|---|---|
| First set of | #0 | cumulative | H |
| memory | #1 | L1 | L |
| cells (e.g., | #2 | L2 | L |
| program | #3 | L3 | L |
| completion | #4 | L4 | L |
| flags) | #5 | L5 | H |
| | #6 | L6 | H |
| | #7 | L7 | H |
| Second set | #10 | cumulative | L |
| of memory | #11 | L1 | L |
| cells (e.g., | #12 | L2 | L |
| SSPC | #13 | L3 | L |
| completion | #14 | L4 | L |
| flags) | #15 | L5 | H |
| | #16 | L6 | H |
| | #17 | L7 | H |

In the example shown in TABLE 1, two sets of memory cells are utilized. These two sets of memory cells configured to operate as the second-type storage include a first set of memory cells referred to as program completion flag cells. The program completion flag cells indicate whether the selected memory cell has reached its target program level. The working principle of these program completion flag cells is discussed in detail below.

Still referring to TABLE 1, the first set of memory cells includes multiple first-level flag memory cells (e.g., #1-#7 in TABLE 1) and a first cumulative flag memory cell (e.g, #0 in TABLE 1). Each first-level flag memory cell indicates whether its corresponding selected memory cell has been programmed to a specific program level. The first cumulative flag memory cell determines, based on data from the first-level flag memory cells, whether the selected memory cell has reached its target program level during a programming operation.

In the example of TABLE 1, the memory cells configured to operate as the first-type storage are tri-level (e.g., TLC) memory cells, which support 8 logic states (L0 to L7). Accordingly, 7 first-level flag memory cells (#1-#7 in TABLE 1) are used, each representing one of the program levels from L1 to L7. If a memory cell is unprogrammed or erased, it is by default at the L0 state. In other examples, the number of first-level flag memory cells may vary based on the number of logic states in the selected memory cells. For example, if the selected memory cells are quad-level (QLC) memory cells with 16 logic states, 15 first-level flag memory cells may be required per selected memory cell.

In some examples, memory cell programming is an iterative process in which program operations and program verify operations alternate. For example, as shown in the example of TABLE 1, if a selected memory cell is targeted to be programmed to L4, it progresses from L0 to L4 gradually through a series of program and program verify operations. During each program verify operation, as previously discussed, the page buffer senses the current program level of the selected memory cell. The page buffer can sense the program level by sensing the current using a sense amplifier, integrating the current to obtain a voltage, and comparing the voltage with a program verification voltage for determining if the selected memory cells has reached a certain threshold voltage corresponding to a logic state. With continued reference to TABLE 1, when the program level reaches L1, the first-level flag memory cell representing L1 (e.g., #1 memory cell) transitions from low to high, indicating that the selected memory cell has reached logic state L1. Similarly, when the program level reaches logic state L2, the first-level flag memory cell representing L2 (e.g., #2 memory cell) transitions from low to high, and so forth. The control logic continues executing program operations until the selected memory cell reaches its target program level, L4 in this example.

TABLE 1 only illustrates an initial state of the two set of memory cells at the beginning of the programming. At the point when the program is finished, all first-level flag memory cells from #1 to #4 transition to high. For a selected memory cell intended to be programmed to L4, the first-level flag memory cells #5 to #7 can be pre-set to high before programming, as shown in TABLE 1. As a result, when the selected memory cell reaches its target program level, all its corresponding first-level flag memory cells (#1-#7) are high.

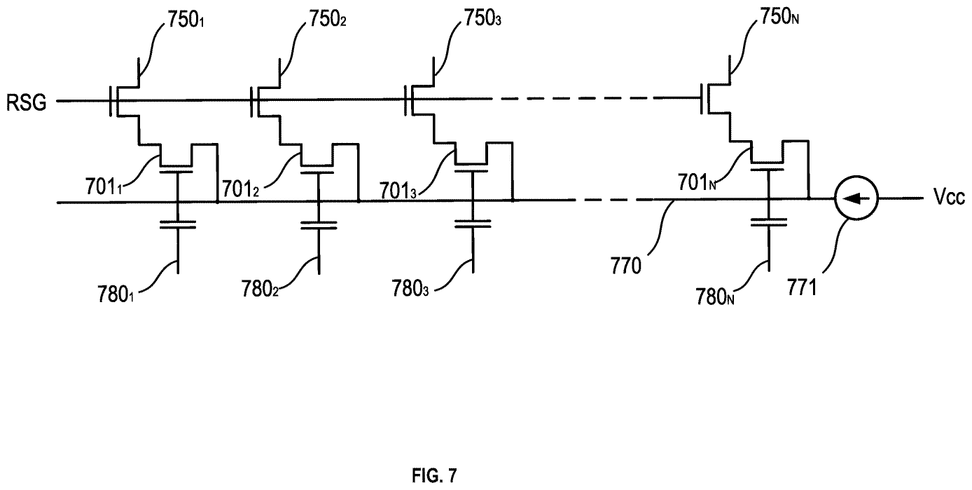

Once all the first-level flag memory cells (#1-#7) transition to high, the first cumulative flag memory cell #0 changes its state, for example, from high to low, to indicate that the selected memory cell has reached its target program level (e.g., L4). The page buffer can then determine whether the selected memory cell has reached its target program level by checking the state of the first cumulative flag memory cell #0. The rationale for using a high-to-low flip here to indicate this condition is explained in greater detail with the embodiment of FIG. 7. However, one skilled in the art will recognize that a low-to-high flip could also be used to represent the same information.

Further referring to TABLE 1, the two sets of the memory cells configured to operate as the second-type storage further includes a second set of memory cells, which, for example, can be SSPC (Slow Step Program Control) completion flag cells. The second set of memory cells includes a plurality of second-level flag memory cells (e.g., #11-#17 in TABLE 1) and a second cumulative flag memory cell (e.g., #10 in TABLE 1). Each second-level flag memory cell indicates whether the corresponding selected memory cell is approaching, but has not yet reached, a specific program level. The second cumulative flag memory cell #10 indicates, based on the flag data from the plurality of second-level flag memory cells, whether the corresponding selected memory cell is approaching its target program level during a program operation.

Similar to the first-level flag memory cells, the number of the second-level flag memory cells in the example of TABLE 1 is 7 (#11-#17), each corresponding to a program level from L1 to L7. In other examples, the number of second-level flag memory cells may vary depending on the number of logic states available in the selected memory cells. The quantity of first-level flag memory cells and second-level flag memory cells may be identical in some examples.

Continuing with the example discussed above, if a selected memory cell is programmed to L4, it progresses from L0 to L4 gradually through a series of program operations and program verify operations. In each program verify operation, as described above, the page buffer senses the current program level of the selected memory cell. When the program level is close to L1 but has not yet reached it, the second-level flag memory cell representing L1 (e.g., #11 memory cell) transitions from low to high, indicating that the selected memory cell is approaching L1. A separate pre-program verification (PPV) level can be used to make the determination of whether the memory cell is approaching a certain logic level (e.g., L1), but has not reached it. Usually, for verification of a certain logic level (e.g., L1), a particular PPV has a voltage that is less than the voltage of PV (e.g., PPV1<PV1). Similarly, when the program level is close to L2 but has not yet reached it, the second-level flag memory cell representing L2 (e.g., #12 memory cell) transitions from low to high, indicating that the selected memory cell is approaching L2. This process continues with the control logic executing program operations until the program level is close to L4, the target program level. After that, all second-level flag memory cells from #11 to #14 transition from low to high. For a selected memory cell intended to be programmed to L4, the second-level flag memory cells from #15 to #17 can be pre-set to high before the programming process begins. Thus, when a selected memory cell is programmed to a level close to its target program level, all corresponding second-level flag memory cells (#11-#17) are high.

Once all the second-level flag memory cells (#11-#17) transition to high, the second cumulative flag memory cell #10 changes its state, for example, from low to high, to indicate that the selected memory cell is approaching its target program level (e.g., L4). The control logic, via the page buffer, can then determine whether the selected memory cell is approaching its target program level by checking the state of the second cumulative flag memory cell #10.

In some examples, the control logic may adjust the program operation based on the states of the two sets of memory cells configured to operate as the second-type storage. Specifically, the control logic may be configured to cause, during a program operation after the program verify operation, the page buffer to apply a voltage to the global bit line to program the corresponding selected memory cell based on the flag data stored in the first and second cumulative flag memory cells.

In some examples, the control logic can be further configured to: in accordance with a determination based on the flag data that the corresponding selected memory cell has not reached its target program level and is not approaching its target program level, cause the page buffer to apply a first voltage to the global bit line to continue the program operation of the corresponding selected memory cell. In accordance with a determination based on the flag data that the corresponding selected memory cell is approaching, but has not yet reached, its target program level, the control logic can cause the page buffer to apply a second voltage to the global bit line to continue the program operation of the corresponding selected memory cell. In accordance with a determination based on the flag data that the corresponding selected memory cell has reached its target program level, the control logic can cause the page buffer to apply an inhibit voltage to stop the program operation of the corresponding selected memory cell. For example, the first voltage may be 0V, the second voltage may be 0.8V, the inhibit voltage is a voltage that is sufficiently high such that the selected memory cell is not programmed anymore (because it has already been programmed to its target logic level).

FIG. 6 is an illustrative schematic of example first and second sub-planes 610 and 620 in a memory device. Sub-planes 610 and 620 can be the same as or similar to sub-planes 510 and 520 as described above. For simplicity, only four sub-blocks (or memory strings) and one dynamic latch device (630 or 640) are shown for each sub-plane in FIG. 6. It is understood that more sub-blocks or blocks can be included in each sub-plane (as shown in FIG. 5) and more dynamic latch devices can be included in each sub-plane. As shown in FIG. 6, the memory device includes two dynamic latch devices 630 and 640. Dynamic device 630 is connected between the first sub-plane 610 and the global bit line 650; and dynamic device 640 is connected between the second sub-plane 620 and the global bit line 650. Each dynamic latch device is coupled to a source line 670 that provides a stable voltage (e.g., Vcc). As a result, a current may flow through a memory cell if there is voltage difference between its respective bit line (e.g., a local bit line) and source line 670. The detailed structure of the dynamic latch device will be described later.

With reference to FIG. 6, the control logic may cause the page buffer 660 to apply a voltage to the global bit line 650 based on the combined states of the first cumulative flag memory cell and the second cumulative flag memory cell, as illustrated by the following cases.

Case 1: If the first cumulative flag memory cell is high and the second cumulative flag memory cell is low, it indicates that the current program level of the selected memory cell is far from its target program level (e.g., L4). In this case, the control logic causes the page buffer 660 to apply the first voltage (e.g., 0V) to the global bit line 650. Meanwhile, the local word line of the selected memory cell is driven with a high program voltage (e.g., 15-20V). This creates a strong electric field needed for electron injections into the floating gate of the selected memory cell. As a result, the large voltage difference between the corresponding local word line and the global bit line enables electron injection, programming the selected memory cell at a faster rate.

Case 2: If both the first and second cumulative flag memory cells are high, it indicates that the selected memory cell is very close to its target program level (e.g., L4). The control logic then causes the page buffer 660 to apply the second voltage (e.g., 0.8V) to the global bit line 650. As a result, the voltage difference between the corresponding local word line and the global bit line reduces, allowing programming to proceed at a slower rate to fine-tune the final level.

Case 3: If the first cumulative flag memory cell is low and the second cumulative flag memory cell is high, it indicates that the selected memory cell has reached its target program level (e.g., L4). The control logic then causes the page buffer 660 to apply a inhibit voltage to the global bit line 650. As a result, the electron injections are inhibited because the voltage difference between the corresponding word line and the global bit line becomes very small or even negative, thereby terminating the program operation.

In some examples, the control logic is further configured to erase the first and second groups of memory cells configured to operate as the second-type storage to reserve them as the cache prior to a program operation. Referring back to FIG. 5, the first and second groups of memory cells configured to operate as the second-type storage 514 and 524 are reserved as a cache for the selected memory cells among the memory cells configured to operate as the first-type storage 512 and 522. Thus, those memory cells configured to operate as the second-type storage need to be erased to function as a temporary cache. This erasing process may involve setting the state of all memory cells operating as second-type storage to a low state.

In some examples, the control logic is further configured to initialize each memory cell of the at least one set of memory cells configured to operate as the second-type storage to an initial state at the beginning of the program operation.

Still referring TABLE 1, if the selected memory cell is planned to be programmed to L4, the first-level flag memory cells representing L5-L7 (e.g., #5-#7 memory cells) and the second-level flag memory cells representing L5-L7 (e.g., #15-#17 memory cells) may be pre-set to high since these program levels do not require verification. The first-level flag memory cells representing L1-L4 (e.g., #1-#4 memory cells) and the second-level flag memory cells representing L1-L4 (e.g., #11-#14 memory cells) may be pre-set to low since these program levels require verification. The first cumulative flag memory cell can be pre-set to high and the second cumulative flag memory cell can be pre-set to low. As programming progresses, once all memory cells representing L1-L4 transition from low to high, the first cumulative flag memory cell #0 will go low, and the second cumulative flag memory cell #10 will go high. Similarly, if a selected memory cell is intended to be programmed to a level other than L4, the flag memory cells corresponding to higher program levels can be pre-set to high, while the flag memory cells corresponding to equal or lower program levels can be pre-set to low at the start of the program operation.

With reference back to FIG. 6, as described above, the memory device includes a first dynamic latch device 630 and a second dynamic latch device 640. The first dynamic latch device 630 is controllably connected between the first sub-plane 610 and the global bit line 650. The second dynamic latch device 640 is controllably connected between the second sub-plane 620 and the global bit line 650. The control logic is further configured to cause a page buffer 660 to sense the selected memory cells during at least one of the one or more data sensing operations; and store the flag data of the selected memory cells in the second or first group of memory cells configured to operate as the second-type storage through the second or first dynamic latch device 640 or 630.

The operation of the dynamic latch device is described next. FIG. 6 illustrates the first and second dynamic latch devices 630 and 640. The two devices act as a bridge between the memory cells on the first sub-plane 610 and the global bit line 650 or between the memory cells on the second sub-plane 620 and the global bit line 650. The second dynamic latch device 640 has a similar structure and function as the first dynamic latch device 630. Data communication between the sub-plane and the global bit line 650 is facilitated through either the first or second dynamic latch device 630 or 640. For example, when the selected memory cell is located on the first sub-plane 610, the page buffer 660 senses the selected memory cells and retrieves the sensed data through the first dynamic latch device 630. The page buffer 660 can then be controlled (e.g., by the control logic) to transfer and store this sensed data in the second sub-plane 620 via the second dynamic latch device 640. As described earlier, the data can be ultimately stored in the second group of memory cells configured to operate as the second-type storage.

With continued reference to FIG. 6, each of the second or first dynamic latch device 640 or 630 further comprises a storage device, a write transistor group and a read transistor group. Take the first dynamic latch device 630 as an example, the write transistor group 631 (denoted as WSG) comprises one or more write transistors connected between the global bit line 650 and the storage device 633. The read transistor group 632 (denoted as RSG) comprises one or more read transistors connected between the storage device 633 and the global bit line 650. The storage device 633 (e.g., a TFT) is connected between one or more read transistors and the source line 670. The storage device 633 is controllable to store the flag data at a sense memory node. During a program operation, the respective dynamic latch device is activated by activating its write transistor group 631 to program the selected memory cell. During the program operation, the read transistor group 632 may be turned off or deactivated. When a program verify operation is in progress, the respective dynamic latch device is activated by activating its read transistor group 632, allowing the page buffer 660 to obtain data from the selected memory cell. During a program verify operation, the write transistor group 631 may be deactivated or turned off. The sensed data can be stored temporarily on the sense memory node (e.g., the gate node of storage device 633), and be transferred to the global bit line 650 under the control of the control logic.

In some examples, the memory device further includes a current meter (an example shown in FIG. 7) connected to the source line and configured to measure a total current flowing through the memory cells configured to operate as a second-type storage. The control logic is configured to determine the flag data stored in the memory cells configured to operate as the second-type storage based on the current measurement provided by the current meter.

FIG. 7 illustrates a schematic of the memory cells configured to operate as the second-type storage within a memory device. The source line 770 in FIG. 7 can be the same as or similar to source line 670 shown in FIG. 6. As previously discussed, the memory cells within a sub-plane are connected between the bit lines and the source line 770, and a current may flow through the memory cell with a low level of program completion flag if there is voltage difference between its respective bit line (e.g., a local bit line) and source line 770. Therefore, a current meter 771 can be connected to the source line 770 and configured to measure the total current flowing through the memory cells configured to operate as the second-type storage.

In the example shown in FIG. 7, there are 131,071 (e.g., N=131,071) selected memory cells that need to be verified. As previously mentioned, each selected memory cell corresponds to a first set of memory cells, which includes a first cumulative flag memory cell. Therefore, the 131,071 selected memory cells correspond to 131,071 first cumulative flag memory cells 701₁-701_{N}, as shown in the figure. The current meter 771 in the schematic can measure the total current flowing through all the first cumulative flag memory cells 701₁-701_{N}.

The bit lines 750₁-750_{N} to which these first cumulative flag memory cells 701₁-701_{N} are connected can be set to 0V when the current meter 771 is measuring the total current, creating a voltage difference between the bit lines 750₁-750_{N} and the source line 770. The word lines 780₁-780_{N} connected to the first cumulative flag memory cells 701₁-701_{N} can be applied with a specific word line voltage during this measurement, ensuring that the first cumulative flag memory cells 701₁-701_{N} can be activated. In FIG. 6, these word lines are denoted as DWLs (or dummy word lines).

As described above, a high-to-low flip is intentionally used to indicate that the selected memory cell has reached its target program level. Thus, for each individual first cumulative flag memory cell (e.g., the memory cell 701₁), if its state is low, there will be no current flowing through it. When all the first cumulative flag memory cells are in the low state, the total current measured by the current meter 771 will be zero (or substantially zero with some negligible leaky current), indicating that all selected memory cells have been successfully programmed to their target program levels.

In some examples, the control logic is further configured to detect, during a program verify operation, a level state of the global bit line; and determine whether the selected memory cells are successfully programmed based on the detected level state of the global bit line. The level state of the global bit line is determined by level states of sense memory nodes in both the first and second dynamic latch devices.

Referring back to FIG. 6, both the first sub-plane 610 and the second sub-plane 620 contain multiple capacitors. As shown, there are four capacitors in each sub-plane: TC00 684 or 688, TC01 682 or 686, TC10 683 or 687, and TC11 681 or 685. The capacitors are used as temporary cache (TC) nodes. If a memory cell in the first sub-plane 610 (e.g., top sub-plane) is selected as the target for programming, TC00 684 can temporarily store the program verification result after the program operation. SGD0 691 or 695 to SGD3 694 or 698 function as switches to these capacitors. The TC nodes are controllably connected to the gate terminal of the storage device 633 for temporarily storing the program verification results.

If the selected memory cell is conductive, indicating it was unsuccessfully programmed, its channel will be low, and TC00 684 will capture the low-level signal. If the selected memory cell is non-conductive, indicating it was successfully programmed, its channel will be high, and TC00 684 will capture the high-level signal. When SGD3 694 in the top sub-plane is ON, the first dynamic latch device 630 provides data indicating whether the selected memory cell has been successfully programmed.

Meanwhile, a capacitor in the second sub-plane 620, such as TC11 685, stores the flag data that indicates whether the selected memory cell has reached its target program level or if it is not expected to reach the program verify level. The second situation arises if the target program level is lower than the program verify level. When SGD0 695 in the bottom sub-plane is ON, the second dynamic latch device 640 can provide this flag data related to the selected memory cell.

If the selected memory cell is not expected to reach the program verify level, the second dynamic latch device 640 will force the global bit line 650 to pull down by activating the TFT 643. In this case, the program verify result from the first dynamic latch device 630 is ignored. Otherwise, if the TFT 643 in the second dynamic latch device 640 is not activated, it does not affect the bit line level, and the bit line level is determined solely by the program verify result output by the first dynamic latch device 630. When it is detected that the selected memory cell has been successfully programmed, the flag data stored in TC11 685 of the second dynamic latch device 640 is updated to reflect the global bit line level (e.g., high level).

In summary, only when both the TFTs 633 and 643 in the first and second dynamic latch devices are inactivated, the global bit line 650 has a high level indicating that the selected memory cell has not yet been programmed. When the TFT 633 in the first dynamic latch device 630 is activated and the TFT 643 in the second dynamic latch device 640 is inactivated, the global bit line 650 has a low level indicating that the selected memory cell is just programmed. When both the TFTs 633 and 643 in the first and second dynamic latch devices are activated, the global bit line 650 has a low level indicating that the selected memory cell has already been programmed before. When TFT 643 in the second dynamic latch device 640 is activated and the TFT 633 in the first dynamic latch device 630 is inactivated, the global bit line 650 has a low level indicating that a program voltage for a higher state is mandatorily ignored. Therefore, the dynamic latch devices enable the implementation of a logic gate (e.g., NOR gate) for providing the programming status, without requiring of using an actual digital logic gate.

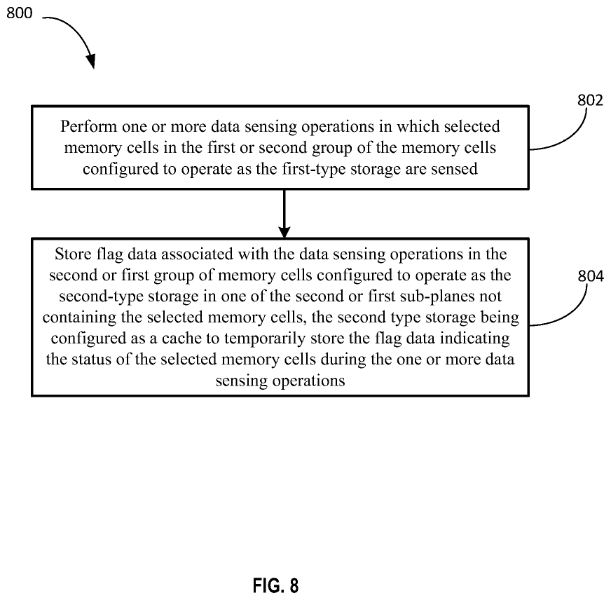

FIG. 8 is a flowchart showing a method 800 performed by the memory device in accordance with examples as disclosed herein. The memory device may include a memory plane that is similar to the memory plane 500 illustrated in FIG. 5. The memory device includes a first sub-plane (e.g., sub-plane 510), a second sub-plane and a global bit line. The global bit line may be similar to the global bit 650 line illustrated in FIG. 6. The first sub-plane comprises a first group of memory cells configured to operate as a first-type storage and a first group of memory cells configured to operate as a second-type storage. The second sub-plane comprises a second group of memory cells configured to operate as the first-type storage and a second group of memory cells configured to operate as the second-type storage. The memory cells configured to operate as a first-type storage may be similar to the memory cells 512 and 522 illustrated in FIG. 5; and the memory cells configured to operate as a second-type storage may be similar to the memory cells 514 and 524 illustrated in FIG. 5. The blocks in FIG. 8 can be performed by the control logic, other components of the memory device (e.g., sense amplifier, page buffer, etc.), or a combination thereof.

Referring to FIG. 8, in block 802, the control logic performs one or more data sensing operations in which selected memory cells in the first or second group of the memory cells configured to operate as the first-type storage are sensed.

In block 804, the control logic stores flag data associated with the data sensing operations in the second or first group of memory cells configured to operate as the second-type storage in one of the second or first sub-planes not containing the selected memory cells, the second type storage being configured as a cache to temporarily store the flag data indicating the status of the selected memory cells during the one or more data sensing operations.

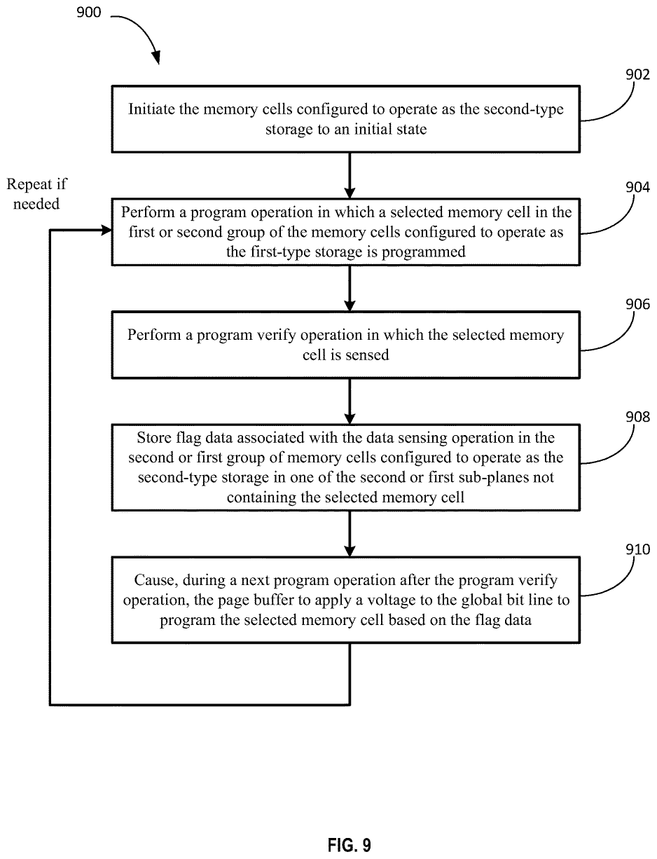

FIG. 9 is a flowchart showing a program method performed by the memory device in accordance with examples as disclosed herein. The memory device may include a memory plane that is similar to the memory plane 500 illustrated in FIG. 5. The memory device includes a first sub-plane, a second sub-plane and a global bit line. The global bit line may be similar to the global bit 650 line illustrated in FIG. 6. The first sub-plane comprises a first group of memory cells configured to operate as a first-type storage and a first group of memory cells configured to operate as a second-type storage. The second sub-plane comprises a second group of memory cells configured to operate as the first-type storage and a second group of memory cells configured to operate as the second-type storage. The memory cells configured to operate as a first-type storage may be similar to the memory cells 512 and 522 illustrated in FIG. 5; and the memory cells configured to operate as a second-type storage may be similar to the memory cells 514 and 524 illustrated in FIG. 5. The blocks in FIG. 9 can be performed by the control logic, other components of the memory device (e.g., sense amplifier, page buffer, etc.), or a combination thereof.

Referring to FIG. 9, in block 902, the control logic initiates the memory cells configured to operate as the second-type storage to an initial state. As discussed with TABLE 1, two sets of memory cells are configured to temporarily store flag data for each corresponding selected memory cell. The first set of memory cells indicates whether the corresponding selected memory cell has been programmed to specific program levels and has reached its target program level. The second set of memory cells indicates whether the corresponding selected memory cell is approaching specific program levels and is approaching its target program level during the program operation. If a selected memory cell is planned to be programmed to a specific level, the flag memory cells in both the first and second sets representing program levels higher than this target program level are pre-set to high. The flag memory cells representing program levels equal to or lower than this target program level are pre-set to low at the beginning of the program operation. Meanwhile, the first cumulative flag memory cell in the first set is set to high, indicating that the selected memory cell has not reached its target program level. The second cumulative flag memory cell in the second set is set to low, indicating that the selected memory cell is not yet approaching its target program level.

In block 904, the control logic performs a program operation in which the selected memory cell in the first or second group of the memory cells configured to operate as the first-type storage is programmed. The control logic may cause page buffer to apply a voltage to the global bit line. As described earlier, the rate of programming depends on the voltage difference between the global bit line and corresponding local word line. During the program operation, the respective dynamic latch device is activated by activating its write transistor group.

In block 906, the control logic performs a program verify operation in which the selected memory cell is sensed. The amplifier in the page buffer is used to sense the data from the selected memory cell. When the program verify operation is in progress, the respective dynamic latch device is activated by activating its read transistor group, allowing the page buffer to obtain data from the selected memory cell.

In block 908, the control logic stores flag data associated with the data sensing operation in the second or first group of memory cells configured to operate as the second-type storage in one of the second or first sub-planes not containing the selected memory cell. The second type storage is configured as a cache to temporarily store the flag data indicating the status of the selected memory cells during one or more data sensing operations. The flag data can be reflected by the state (e.g., “high” or “low”) of the memory cells configured to operate as the second-type storage.

In block 910, the control logic causes, during a next program operation after the program verify operation, the page buffer to apply a voltage to the global bit line to program the selected memory cell based on the flag data. In accordance with a determination based on the flag data that the corresponding selected memory cell has not reached its target program level and is not approaching its target program level, the control logic can cause the page buffer to apply a first voltage to the global bit line to continue the program operation of the corresponding selected memory cell. In accordance with a determination based on the flag data that the corresponding selected memory cell is approaching, but has not yet reached, its target program level, the control logic can cause the page buffer to apply a second voltage to the global bit line to continue, but in a slower rate, the program operation of the corresponding selected memory cell. In accordance with a determination based on the flag data that the corresponding selected memory cell has reached its target program level, the control logic can cause the page buffer to apply an inhibit voltage to stop the program operation of the corresponding selected memory cell.

The page buffer then applies the voltage determined in block 910 to the global bit line, repeating both the program operation and the program verify operation. If the page buffer applies an inhibit voltage to the global bit line, the program operation is terminated, and the control logic ends the entire process.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller or control logic isolates two components, the controller or control logic affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

### ADDITIONAL EXAMPLES

Example 1: A memory device comprising: a memory plane comprising: a first sub-plane comprising a first group of memory cells configured to operate as a first-type storage and a first group of memory cells configured to operate as a second-type storage; and a second sub-plane comprising a second group of memory cells configured to operate as the first-type storage and a second group of memory cells configured to operate as the second-type storage; a global bit line coupled to both the first sub-plane and the second sub-plane; and control logic configured to: perform one or more data sensing operations in which selected memory cells in the first or second group of the memory cells configured to operate as the first-type storage are sensed; and store flag data associated with the data sensing operations in the second or first group of memory cells configured to operate as the second-type storage in one of the second or first sub-planes not containing the selected memory cells, the second-type storage being configured as a cache to temporarily store the flag data indicating the status of the selected memory cells during the one or more data sensing operations.

Example 2: The memory device of example 1, wherein: the one or more data sensing operations comprise a program verify operation, and at least one set of the memory cells configured to operate as the second-type storage is configured to temporarily store the flag data for each corresponding selected memory cell, the at least one set of the memory cells configured to operate as the second-type storage comprising: a first set of memory cells comprising: a plurality of first-level flag memory cells, each indicating whether the corresponding selected memory cell has been programmed to a specific program level; and a first cumulative flag memory cell indicating, based on the flag data from the plurality of first-level flag memory cells, whether the corresponding selected memory cell has been programmed to its target program level during a program operation.

Example 3: The memory device of example 2, wherein the at least one set of the memory cells configured to operate as the second-type storage further comprises: a second set of memory cells comprising: a plurality of second-level flag memory cells, each indicating whether the corresponding selected memory cell is approaching a specific program level; and a second cumulative flag memory cell indicating, based on the flag data from the plurality of second-level flag memory cells, whether the corresponding selected memory cell is approaching its target program level during a program operation.

Example 4: The memory device of example 3, further comprising: a page buffer connected to the global bit line, wherein the control logic is configured to: cause, during a program operation after the program verify operation, the page buffer to apply a voltage to the global bit line to program the corresponding selected memory cell based on the flag data stored in the first and second cumulative flag memory cells.

Example 5: The memory device of example 4, wherein the control logic is further configured to: in accordance with a determination based on the flag data that the corresponding selected memory cell has not reached its target program level and is not approaching its target program level, cause the page buffer to apply a first voltage to the global bit line to continue the program operation of the corresponding selected memory cell; in accordance with a determination based on the flag data that the corresponding selected memory cell is approaching, but has not yet reached, its target program level, cause the page buffer to apply a second voltage different from the first voltage to the global bit line to continue the program operation of the corresponding selected memory cell; and in accordance with a determination based on the flag data that the corresponding selected memory cell has reached its target program level, cause the page buffer to apply an inhibit voltage to stop the program operation of the corresponding selected memory cell.

Example 6: The memory device of any of examples 4-5, wherein the control logic is further configured to: erase the first and second groups of memory cells configured to operate as the second-type storage to reserve them as the cache prior to a program operation.

Example 7: The memory device of example 6, wherein the control logic is further configured to: initialize each memory cell of the at least one set of memory cells configured to operate as the second-type storage to an initial state at the beginning of the program operation.

Example 8: The memory device of any of examples 1-7, further comprising: a first dynamic latch device controllably connected between the first sub-plane and the global bit line; and a second dynamic latch device controllably connected between the second sub-plane and the global bit line, wherein the control logic is further configured to: cause a page buffer to sense the selected memory cells during at least one of the one or more data sensing operations; and store the flag data of the selected memory cells in the second or first group of memory cells configured to operate as the second-type storage through the second or first dynamic latch device.

Example 9: The memory device of example 8, wherein the second or first dynamic latch device further comprises: a storage device; a write transistor group comprising one or more write transistors connected between the global bit line and the storage device; and a read transistor group comprising one or more read transistors connected between the storage device and the global bit line; wherein: the storage device is connected between the one or more read transistors and a source line, the storage device being controllable to store the flag data at a sense memory node.

Example 10: The memory device of example 9, further comprising: a current meter connected to the source line and configured to measure a total current flowing through at least a portion of the memory cells configured to operate as the second-type storage, wherein the control logic is further configured to: determine the flag data stored in the memory cells configured to operate as the second-type storage based on the current measurement provided by the current meter.

Example 11: The memory device of any of examples 9-10, the control logic is further configured to: detect, during a program verify operation, a level state of the global bit line, wherein the level state of the global bit line is determined by level states of sense memory nodes in both the first and second dynamic latch devices; and determine whether the selected memory cells are successfully programmed based on the detected level state of the global bit line.

Example 12: The memory device of any of examples 1-11, wherein memory cells configured to operate as the first-type storage comprise tri-level or quad-level memory cells.

Example 13: The memory device of any of examples 1-12, wherein the first-type storage is a non-volatile storage, and the second-type storage is a volatile storage.

Example 14: A method performed by a memory device comprising a first sub-plane, a second sub-plane and a global bit line wherein the first sub-plane comprises a first group of memory cells configured to operate as a first-type storage and a first group of memory cells configured to operate as a second-type storage; and the second sub-plane comprises a second group of memory cells configured to operate as the first-type storage and a second group of memory cells configured to operate as the second-type storage, the method comprising: performing one or more data sensing operations in which selected memory cells in the first or second group of the memory cells configured to operate as the first-type storage are sensed; and storing flag data associated with the data sensing operations in the second or first group of memory cells configured to operate as the second-type storage in one of the second or first sub-planes not containing the selected memory cells, the second type storage being configured as a cache to temporarily store the flag data indicating the status of the selected memory cells during the one or more data sensing operations.

Example 15: A method performed by a memory device comprising a first sub-plane, a second sub-plane, a global bit line and a page buffer connected to the global bit line, wherein the first sub-plane comprises a first group of memory cells configured to operate as a first-type storage and a first group of memory cells configured to operate as a second-type storage; and the second sub-plane comprises a second group of memory cells configured to operate as the first-type storage and a second group of memory cells configured to operate as the second-type storage, the method comprising: initiating the memory cells configured to operate as the second-type storage to an initial state; performing a program operation in which a selected memory cell in the first or second group of the memory cells configured to operate as the first-type storage is programmed; performing a program verify operation in which the selected memory cell is sensed; storing flag data associated with the data sensing operation in the second or first group of memory cells configured to operate as the second-type storage in one of the second or first sub-planes not containing the selected memory cell; and causing, during a next program operation after the program verify operation, the page buffer to apply a voltage to the global bit line to program the selected memory cell based on the flag data.

What is claimed is:

1. A memory device comprising:
a memory plane comprising:
a first sub-plane comprising a first group of memory cells configured to operate as a first-type storage and a first group of memory cells configured to operate as a second-type storage; and
a second sub-plane comprising a second group of memory cells configured to operate as the first-type storage and a second group of memory cells configured to operate as the second-type storage;
a global bit line coupled to both the first sub-plane and the second sub-plane; and
control logic configured to:
perform one or more data sensing operations in which selected memory cells in the first or second group of the memory cells configured to operate as the first-type storage are sensed; and
store flag data associated with the data sensing operations in the second or first group of memory cells configured to operate as the second-type storage in one of the second or first sub-planes not containing the selected memory cells, the second-type storage being configured as a cache to temporarily store the flag data indicating the status of the selected memory cells during the one or more data sensing operations.

2. The memory device of claim 1, wherein:
the one or more data sensing operations comprise a program verify operation, and
at least one set of the memory cells configured to operate as the second-type storage is configured to temporarily store the flag data for each corresponding selected memory cell,
the at least one set of the memory cells configured to operate as the second-type storage comprising:
a first set of memory cells comprising:
a plurality of first-level flag memory cells, each indicating whether the corresponding selected memory cell has been programmed to a specific program level; and
a first cumulative flag memory cell indicating, based on the flag data from the plurality of first-level flag memory cells, whether the corresponding selected memory cell has been programmed to its target program level during a program operation.

3. The memory device of claim 2, wherein the at least one set of the memory cells configured to operate as the second-type storage further comprises:
a second set of memory cells comprising:
a plurality of second-level flag memory cells, each indicating whether the corresponding selected memory cell is approaching a specific program level; and
a second cumulative flag memory cell indicating, based on the flag data from the plurality of second-level flag memory cells, whether the corresponding selected memory cell is approaching its target program level during a program operation.

4. The memory device of claim 3, further comprising:
a page buffer connected to the global bit line, wherein the control logic is configured to:
cause, during a program operation after the program verify operation, the page buffer to apply a voltage to the global bit line to program the corresponding selected memory cell based on the flag data stored in the first and second cumulative flag memory cells.

5. The memory device of claim 4, wherein the control logic is further configured to:
in accordance with a determination based on the flag data that the corresponding selected memory cell has not reached its target program level and is not approaching its target program level, cause the page buffer to apply a first voltage to the global bit line to continue the program operation of the corresponding selected memory cell;
in accordance with a determination based on the flag data that the corresponding selected memory cell is approaching, but has not yet reached, its target program level, cause the page buffer to apply a second voltage different from the first voltage to the global bit line to continue the program operation of the corresponding selected memory cell; and
in accordance with a determination based on the flag data that the corresponding selected memory cell has reached its target program level, cause the page buffer to apply an inhibit voltage to stop the program operation of the corresponding selected memory cell.

6. The memory device of claim 4, wherein the control logic is further configured to:
erase the first and second groups of memory cells configured to operate as the second-type storage to reserve them as the cache prior to a program operation.

7. The memory device of claim 6, wherein the control logic is further configured to:
initialize each memory cell of the at least one set of memory cells configured to operate as the second-type storage to an initial state at the beginning of the program operation.

8. The memory device of claim 1, further comprising:
a first dynamic latch device controllably connected between the first sub-plane and the global bit line; and
a second dynamic latch device controllably connected between the second sub-plane and the global bit line, wherein the control logic is further configured to:
cause a page buffer to sense the selected memory cells during at least one of the one or more data sensing operations; and
store the flag data of the selected memory cells in the second or first group of memory cells configured to operate as the second-type storage through the second or first dynamic latch device.

9. The memory device of claim 8, wherein the second or first dynamic latch device further comprises:
a storage device;
a write transistor group comprising one or more write transistors connected between the global bit line and the storage device; and
a read transistor group comprising one or more read transistors connected between the storage device and the global bit line; wherein:
the storage device is connected between the one or more read transistors and a source line, the storage device being controllable to store the flag data at a sense memory node.

10. The memory device of claim 9, further comprising:
a current meter connected to the source line and configured to measure a total current flowing through at least a portion of the memory cells configured to operate as the second-type storage,
wherein the control logic is further configured to:
determine the flag data stored in the memory cells configured to operate as the second-type storage based on the current measurement provided by the current meter.

11. The memory device of claim 9, the control logic is further configured to:
detect, during a program verify operation, a level state of the global bit line, wherein the level state of the global bit line is determined by level states of sense memory nodes in both the first and second dynamic latch devices; and
determine whether the selected memory cells are successfully programmed based on the detected level state of the global bit line.

12. The memory device of claim 1, wherein memory cells configured to operate as the first-type storage comprise tri-level or quad-level memory cells.

13. The memory device of claim 1, wherein the first-type storage is a non-volatile storage, and the second-type storage is a volatile storage.

14. A method performed by a memory device comprising a first sub-plane, a second sub-plane and a global bit line wherein the first sub-plane comprises a first group of memory cells configured to operate as a first-type storage and a first group of memory cells configured to operate as a second-type storage; and the second sub-plane comprises a second group of memory cells configured to operate as the first-type storage and a second group of memory cells configured to operate as the second-type storage, the method comprising:
performing one or more data sensing operations in which selected memory cells in the first or second group of the memory cells configured to operate as the first-type storage are sensed; and
storing flag data associated with the data sensing operations in the second or first group of memory cells configured to operate as the second-type storage in one of the second or first sub-planes not containing the selected memory cells, the second type storage being configured as a cache to temporarily store the flag data indicating the status of the selected memory cells during the one or more data sensing operations.

15. A method performed by a memory device comprising a first sub-plane, a second sub-plane, a global bit line and a page buffer connected to the global bit line, wherein the first sub-plane comprises a first group of memory cells configured to operate as a first-type storage and a first group of memory cells configured to operate as a second-type storage; and the second sub-plane comprises a second group of memory cells configured to operate as the first-type storage and a second group of memory cells configured to operate as the second-type storage, the method comprising:
initiating the memory cells configured to operate as the second-type storage to an initial state;
performing a program operation in which a selected memory cell in the first or second group of the memory cells configured to operate as the first-type storage is programmed;
performing a program verify operation in which the selected memory cell is sensed;
storing flag data associated with the data sensing operation in the second or first group of memory cells configured to operate as the second-type storage in one of the second or first sub-planes not containing the selected memory cell; and
causing, during a next program operation after the program verify operation, the page buffer to apply a voltage to the global bit line to program the selected memory cell based on the flag data.
